(19) United States
(12) Patent Application Publication
(10) Pub. No.: US 2008/0246056 A1
(43) Pub. Date: Oct. 9, 2008

(54) SILICIDE FORMATION FOR eSiGe USING SPACER OVERLAPPING eSiGe AND SILICON CHANNEL INTERFACE AND RELATED PFET

(76) Inventors: Victor W. C. Chan, Newburgh, NY (US); Thomas W. Dyer, Pleasant Valley, NY (US); Sunfei Fang, LaGrangeville, NY (US); Jinghong Li, Poughquag, NY (US); Teck J. Tang, Johor Bahru (MY); Henry K. Utomo, Newburgh, NY (US); Jiang Yan, Newburgh, NY (US)

Correspondence Address: HOFFMAN WARNICK LLC, 75 STATE ST, 14TH FL, ALBANY, NY, 12207, US

(21) Appl. No.: 11/697,806

(22) Filed: Apr. 9, 2007

(51) Int. Cl. H01L 29/778; H01L 21/336

(52) U.S. Cl. 257/190; 438/300; 257/E21.409; 257/E29.246

(57) ABSTRACT

Methods of forming a suicide in an embedded silicon germanium (eSiGe) source/drain region using a suicide prevention spacer overlapping an interface between the eSiGe and the silicon channel, and a related PFET with an eSiGe source/drain region and a compressive stress liner in close proximity to a silicon channel thereof, are disclosed. In one embodiment, a method includes providing a gate having a nitrogen-containing spacer adjacent thereto and an epitaxially grown silicon germanium (eSiGe) region adjacent to a silicon channel of the gate; removing the nitrogen-containing spacer that does not extend over the interface between the eSiGe source/drain region and the silicon channel; forming a single silicide prevention spacer about the gate, the single silicide prevention spacer overlapping the interface; and forming the silicide in the eSiGe source/drain region using the single silicide prevention spacer to prevent the silicide from forming in at least an extension area of the silicon channel.

### BACKGROUND

1. Technical Field

The disclosure relates generally to integrated circuit (IC) fabrication, and more particularly, to methods of forming a silicide in embedded silicon germanium (eSiGe) source/drain regions using a silicide prevention spacer overlapping an interface between the eSiGe and the silicon channel, and a related PFET.

2. Background Art

Compressive stress along a device channel increases drive current in p-type field effect transistors (PFETs) and decreases drive current in n-type field effect transistors (NFETs). Similarly, tensile stress along the device channel increases drive current in NFETs and decreases drive current in PFETs. In integrated circuits (IC), embedded epitaxially grown silicon germanium (eSiGe) is used in active regions of FETs to improve performance. In particular, eSiGe source/drain regions are known to improve the performance of PFETs by inducing compressive stress into the channel due to the lattice mis-match between the SiGe and the silicon (Si) of the channel. One challenge relative to the use of eSiGe, however, is formation of suicide therein. In particular, during salicidation of the eSiGe, the suicide is formed at higher temperatures than in Si, which results in silicide quickly spreading into an adjacent silicon extension area of the channel of the FET, if both SiGe and Si are exposed to silicide forming metal material. This presents a problem for PFETs. In particular, as noted above, PFETs perform better when the channels thereof are under compressive stress via, for example, the stress proximity technique (SPT) in which intrinsically compressively stressed liners are placed over the PFETs with close proximity to compressively stress the channel. The silicide, however, is intrinsically tensilely stressed. Thus, the silicide extending beyond the eSiGe acts to diminish the compressive stress from the eSiGe that may be applied to the channel of a PFET.

One approach to overcome this situation, as shown in FIG. 1, is to provide an additional spacer 10 next to a spacer 11 of a polysilicon gate 12 of, for example, a PFET 14 having eSiGe source/drain regions 16. The use of additional spacer 10 prevents formation of silicide 20 into silicon channel 22. However, additional spacer 10 hinders the use of the SPT. In particular, the additional spacer 10 typically includes a layer of silicon oxide 24 covered by a layer of silicon nitride 26 adjacent to a typical silicon nitride spacer 11. During SPT, an intrinsically compressively stressed silicon nitride liner (not shown) is placed over PFET 14 after removal of all of its spacers, to maximize the stress in channel 22 from the stress liner. The removal of additional spacer 10 together with spacer 11 is difficult since they consist of both silicon nitride areas 26, 11 and silicon oxide area 24. In addition, the etching, e.g., a reactive ion etch (RIE) or a wet etch, to remove spacer 10 and 11 has to be selective to silicon oxide, i.e., to low temperature oxide (LTO) 29 under spacer 11 and an inner silicon oxide spacer 32 about gate 12, to prevent attack on silicon extension region 23, gate oxide 30, and/or polysilicon gate 12. Consequently, the etching does not remove layer of silicon oxide 24 of additional spacer 10, which prevents stress from being imparted to channel 22.

### SUMMARY

Methods of forming a silicide in an embedded silicon germanium (eSiGe) source/drain region using a silicide prevention spacer overlapping an interface between the eSiGe and the silicon channel, and a related PFET with an eSiGe source/drain region and a compressive stress liner in close proximity to a silicon channel thereof, are disclosed. In one embodiment, a method includes providing a gate having a nitrogen-containing spacer adjacent thereto and an epitaxially grown silicon germanium (eSiGe) region adjacent to a silicon channel of the gate; removing the nitrogen-containing spacer that does not extend over the interface between the eSiGe source/drain region and the silicon channel; forming a single silicide prevention spacer about the gate, the single silicide prevention spacer overlapping the interface; and forming the silicide in the eSiGe source/drain region using the single silicide prevention spacer to prevent the silicide from forming in at least an extension area of the silicon channel.

A first aspect of the disclosure provides a method comprising: providing a gate having a nitrogen containing spacer adjacent thereto and an epitaxially grown silicon germanium (eSiGe) source/drain region adjacent to a silicon channel of the gate; removing the nitrogen containing spacer that does not extend over the interface between the eSiGe source/drain region and the silicon channel; forming a single silicide prevention spacer about the gate, the single silicide prevention spacer overlapping the interface; and forming the silicide in the eSiGe source/drain region using the single silicide prevention spacer to prevent the silicide from forming in at least an extension area of the silicon channel.

A second aspect of the disclosure provides a PFET comprising: a gate having an embedded silicon germanium (eSiGe) source/drain region adjacent to a silicon channel of the gate and a thin spacer adjacent to the gate; a silicide entirely in the eSiGe source/drain region, the silicide distanced from the silicon channel; and a compressive stress liner over the gate and the thin spacer and in close proximity to the silicon channel and the gate.

The illustrative aspects of the present disclosure are designed to solve the problems herein described and/or other problems not discussed.

### BRIEF DESCRIPTION OF THE DRAWINGS

These and other features of this disclosure will be more readily understood from the following detailed description of the various aspects of the disclosure taken in conjunction with the accompanying drawings that depict various embodiments of the disclosure, in which:

FIG. 1 shows a conventional method of forming silicide for a transistor including an eSiGe source/drain region.

FIGS. 2-6 show embodiments of a method according to the disclosure, with FIG. 6 showing embodiments of a related PFET according to the disclosure.

It is noted that the drawings of the disclosure are not to scale. The drawings are intended to depict only typical aspects of the disclosure, and therefore should not be considered as limiting the scope of the disclosure. In the drawings, like numbering represents like elements between the drawings.

### DETAILED DESCRIPTION

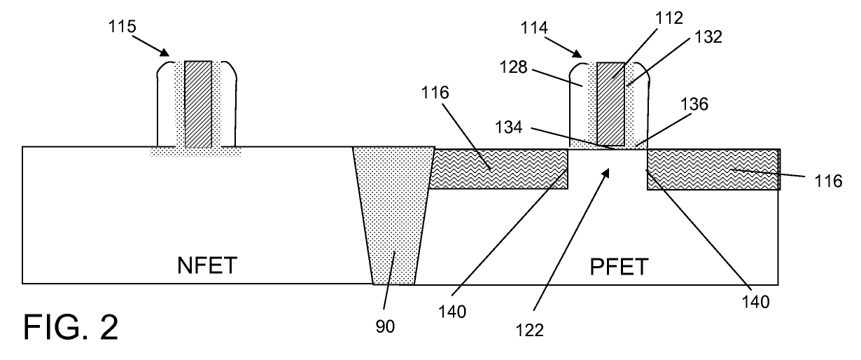

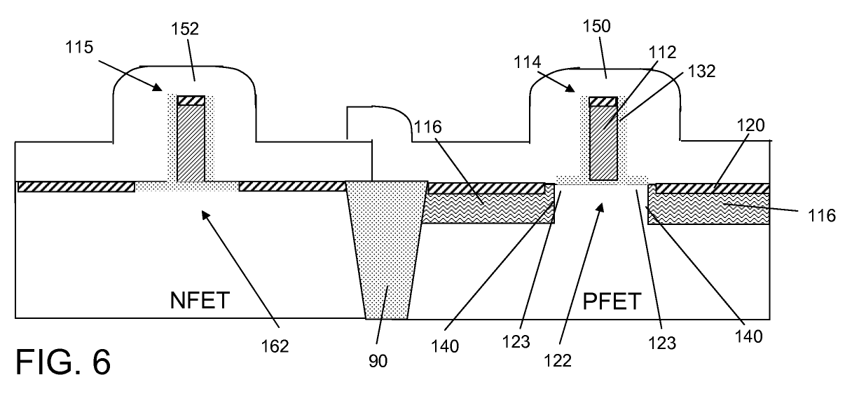

FIGS. 2-6 show embodiments of a method according to the disclosure, with FIG. 6 showing embodiments of a related PFET 114 according to the disclosure. FIG. 2 shows PFET 114 and an NFET 115 adjacent thereto. The teachings of the disclosure will be shown applied to PFET 114 only since embedded epitaxially grown silicon germanium (eSiGe) source/drain region 116 is typically used with PFETs 114 only. However, as will be apparent herein, NFET 115 may be processed simultaneously with PFET 114. While only one NFET 115 and one PFET 114 are shown, it is understood that millions could be present in any integrated circuit (IC). FETs 114, 115 are separated by isolation region(s) 90, e.g., of silicon oxide.

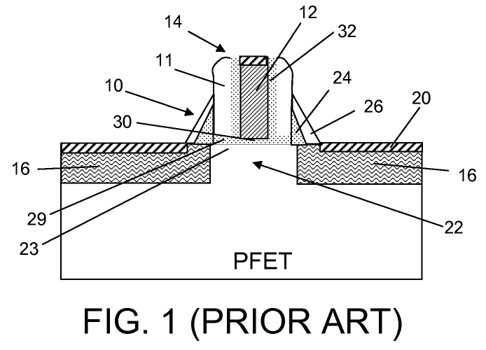

FIG. 2 shows providing a gate 112 having an eSiGe source/drain region 116 (two shown) adjacent to a silicon channel region 122 of gate 112. Gate 112 may include: polysilicon, metal (e.g., aluminum (Al), tungsten (W), aluminum (AlN), titanium nitride (TiN) and tantalum nitride (TaN), etc.) or a combination of polysilicon and metal. An inner thin spacer 132 is formed next to gate 112 and an optional, initial nitrogen-containing spacer 128 is formed adjacent to inner thin spacer 132. Thin spacer 132 may have a thickness of approximately 0.1 nanometers (nm) to approximately 20 nm, i.e., ±0.05 nm, and may include, for example, silicon oxide or silicon oxynitride. Nitrogen-containing spacer 128 may include, for example, silicon nitride and/or silicon oxynitride. Initial nitrogen-containing spacer 128 does not extend laterally to eSiGe source/drain region 116, i.e., it does not extend over an interface 140 between channel region 122 and eSiGe source/drain region 116. As a result, as described relative to FIG. 1, were silicide formed using initial nitrogen-containing spacer 128, silicide would extend into silicon channel 122. Gate 112 may also include a silicon oxide gate dielectric layer 134 under gate 112 and an etch stop layer 136 (e.g., silicon oxide or silicon oxynitride) under at least thin spacer 132 (shown extending to interface 140). All of the above structure may be formed using any now known or later developed techniques, e.g., deposition, photolithography, patterning, etching, etc.

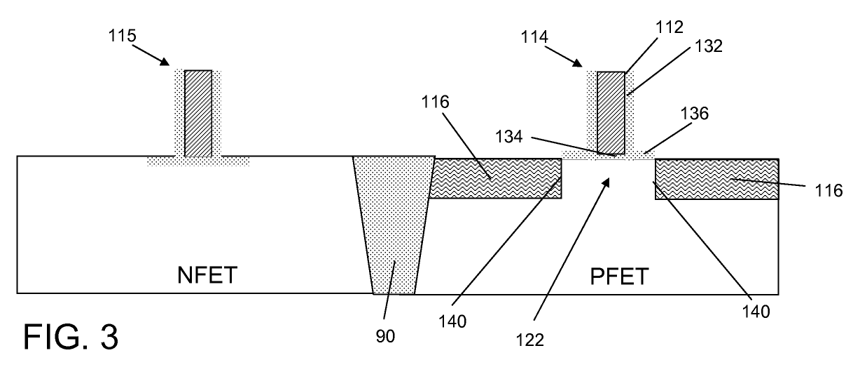

FIG. 3 shows removing initial nitrogen-containing spacer 128 (FIG. 2) about gate 112 to expose inner thin spacer 132. Nitrogen-containing spacer 128 may be removed using any appropriate etching process, e.g., a reaction ion etch (RIE), selective to inner thin spacer 132 and eSiGe source/drain region 116.

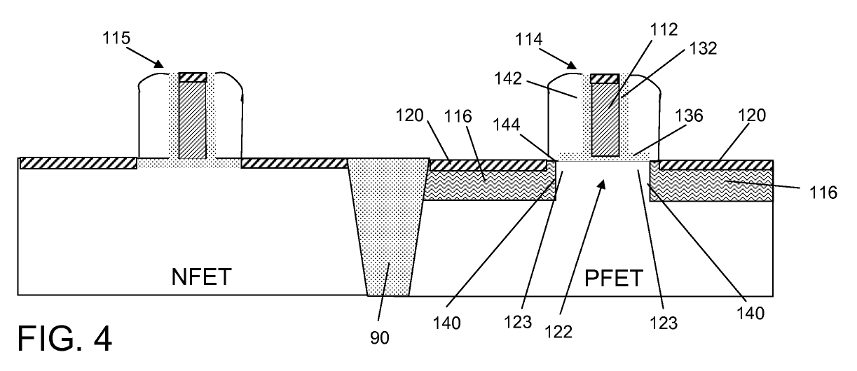

FIG. 4 shows forming a single silicide prevention spacer 142 about gate 112 (and inner thin spacer 132). Single silicide prevention spacer 142 may include, for example, silicon nitride or silicon oxynitride. Single silicide prevention spacer 142 is larger than initial nitrogen-containing spacer 128 (FIG. 2) and overlaps interface 140 between eSiGe source/drain region 116 and silicon channel 122. “Overlap,” as used herein, means at least a lower surface 144 of single silicide prevention spacer 142 extends laterally over interface 140 such that interface 140 is not exposed.

Forming a silicide 120 in eSiGe source/drain region 116 using silicide prevention spacer 142 to prevent the silicide from forming in at least an extension area 123 of silicon channel 122 is also shown in FIG. 4. Silicide 120 is also formed for NFET 115. Silicide 120 may be formed using any now known or later developed technique, e.g., depositing a metal such as titanium, nickel, cobalt, etc., annealing to have the metal react with eSiGe source/drain region 116, and removing unreacted metal. Single silicide prevention spacer 142 prevents silicide 120 from forming in silicon channel 122, resulting in silicide 120 being distanced from silicon channel, i.e., distanced from interface 140 by the length that single silicide prevention spacer 142 extends beyond interface 140.

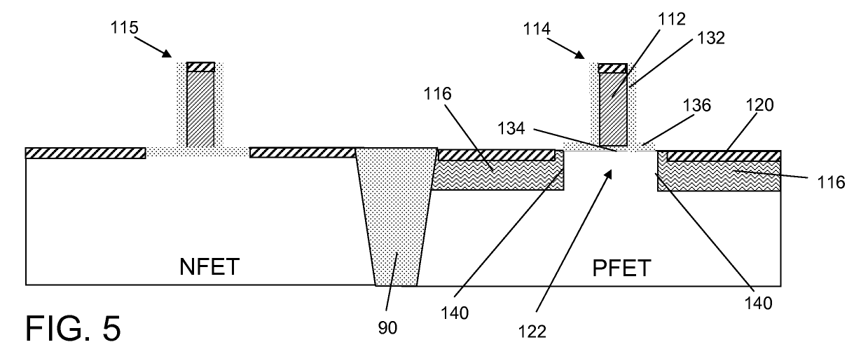

FIGS. 5-6 show an optional process for implementing a stress proximity technique. In FIG. 5, single silicide prevention spacer 142 (FIG. 4) is removed about gate 112, e.g., by a reactive ion etch (RIE) selective to inner thin spacer 132. That is, inner thin spacer 132 remains during the removing of single silicide prevention spacer 142. As shown in FIG. 6, an intrinsically stressed liner 150 is then applied (deposited) over gate 112 and eSiGe source/drain region 116 to impart a stress to silicon channel 122. FIG. 6 shows use of a dual stress liner including an intrinsically compressive stress liner 150 for PFET 114. Optionally, an intrinsically tensile stress liner 152 for NFET 115 may be used. However, the liners 150, 152 may be used individually.

FIG. 6 also shows a related PFET 114 including gate 112 having eSiGe source/drain region 116 adjacent to silicon channel 122 of gate 112 and thin spacer 132 adjacent to gate 112. Silicide 120 is entirely in eSiGe source/drain region 116, and the silicide is distanced from an extension region 123 of silicon channel 122, and the rest of silicon channel 122. Compressive stress liner 150 is provided over gate 112 and thin spacer 132 and in close proximity (<1.0 nm) to silicon channel 122 and thin spacer 132.

The method as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The foregoing description of various aspects of the disclosure has been presented for purposes of illustration and description. It is not intended to be exhaustive or to limit the disclosure to the precise form disclosed, and obviously, many modifications and variations are possible. Such modifications and variations that may be apparent to a person skilled in the art are intended to be included within the scope of the disclosure as defined by the accompanying claims.

What is claimed is:

1. A method comprising:
providing a gate having a nitrogen containing spacer adjacent thereto and an epitaxially grown silicon germanium (eSiGe) source/drain region adjacent to a silicon channel of the gate;
removing the nitrogen containing spacer that does not extend over the interface between the eSiGe source/drain region and the silicon channel;
forming a single silicide prevention spacer about the gate, the single silicide prevention spacer overlapping the interface; and
forming the silicide in the eSiGe source/drain region using the single silicide prevention spacer to prevent the silicide from forming in at least an extension area of the silicon channel.

2. The method of claim 1, further comprising:
removing the single silicide prevention spacer about the gate; and
applying an intrinsically stressed liner over the gate and the eSiGe source/drain region to impart a stress to the silicon channel.

3. The method of claim 2, wherein the intrinsically stressed liner is compressive for a PFET.

4. The method of claim 2, wherein the providing includes providing an inner silicon oxide spacer about the gate, the inner silicon oxide spacer remaining during the removing of the single silicide prevention spacer.

5. The method of claim 2, wherein the providing further includes providing an etch stop layer under the silicon oxide spacer.

6. The method of claim 1, wherein the single silicide prevention spacer includes one of silicon nitride and silicon oxynitride.

7. A PFET comprising:
a gate having an embedded silicon germanium (eSiGe) source/drain region adjacent to a silicon channel of the gate and a thin spacer adjacent to the gate;
a silicide entirely in the eSiGe source/drain region, the silicide distanced from the silicon channel; and
a compressive stress liner over the gate and the thin spacer and in close proximity to the silicon channel and the thin spacer.

8. The PFET of claim 7, wherein the thin spacer has a thickness of approximately 0.1 nanometers (nm) to approximately 20 nm.

9. The PFET of claim 7, wherein the thin spacer includes one of silicon oxide or silicon oxynitride.

10. The PFET of claim 7, wherein the gate includes one of: polysilicon, metal or a combination of polysilicon and metal.

11. The PFET of claim 10, wherein the metal is selected from the group consisting of: aluminum (Al), tungsten (W), aluminum (AlN), titanium nitride (TiN) and tantalum nitride (TaN).
